(19) United States
(12) Patent Application Publication
(10) Pub. No.: US 2017/0213785 A1
(43) Pub. Date: Jul. 27, 2017

(54) METHOD OF FORMING SOLDER BUMPS ON SOLID STATE MODULE INCLUDING PRINTED CIRUCUIT BOARD

(71) Applicant: Avago Technologies General IP (Singapore) Pte. Ltd., Singapore (SG)

(72) Inventor: Nitesh Kumbhat, San Jose, CA (US)

(21) Appl. No.: 15/004,468

(22) Filed: Jan. 22, 2016

(51) Int. Cl. H01L 23/498; H01L 23/31; H01L 21/48; H01L 21/66; H01L 21/683

(52) U.S. Cl. CPC H01L 23/49816; H01L 22/14; H01L 21/6835; H01L 21/4853; H01L 21/4867; H01L 23/49866; H01L 23/3114; H01L 23/3128; H01L 23/49894; H01L 2221/68359

(57) ABSTRACT

A method is provided for forming solder bumps on at least one module including a printed circuit board (PCB), electronic circuitry, and metal pads connected to the electronic circuitry. The metal pads are arranged in a predetermined pattern on a surface of the PCB. The method includes providing a planar structure including a non-wettable surface; placing a stencil over the non-wettable surface, the stencil defining openings corresponding to the metal pads; applying solder paste through the openings in the stencil to provide corresponding solder paste deposits on the non-wettable surface; removing the stencil; placing the at least one module on the solder paste deposits, such that the metal pads align with the solder paste deposits, respectively; and reflowing the solder paste deposits to form corresponding solder bumps, which respectively adhere to the metal pads of the at least one module and not to the non-wettable surface of the planar structure.

### BACKGROUND

There is increasing demand for smaller electronic devices, particularly with respect to radio frequency (RF) wireless communication products, for example. These products typically include solid state modules (or packages) having various features, such as electronic circuitry and components attached to and/or embedded in a printed circuit board (PCB), molded compound applied to a surface of the PCB to protect the electrical circuitry and components, and conductive (e.g., metal) pads formed on an opposite surface of the PCB to accommodate subsequent mounting (e.g., using solder) of the modules within the electronic devices, possibly on another PCB. Various different types of modules (or packages) include a land grid array (LGA) module, a quad flat no-lead (QFN) module, a chip scale package (CSP), and a wafer level package (WLP), for example. The corresponding metal pads are connected to the electronic circuitry and arranged in a predetermined pattern on the opposite surface of the PCB.

The solid state modules that are shipped by the manufacturer with solder bumps in place enable tighter placement of the modules on boards of the customer product. Solder bumping may be done on a strip level before singulation, but this impacts and requires alterations to the downstream processes, such as electromagnetic interference (EMI) shielding, RF testing, and the like. Therefore, there is need for fabrication processes that provide solder bumps on parts at the end-of-line stage. The conventional techniques for providing solder bumps include solder ball drop, solder preform, and the like, which are limited to larger package sizes and/or limit the flexibility in defining solder volume per metal pad, e.g., on LGA modules, QFN modules, CSPs, and/or WLPs, for example.

### BRIEF DESCRIPTION OF THE DRAWINGS

The illustrative embodiments are best understood from the following detailed description when read with the accompanying drawing figures. It is emphasized that the various features are not necessarily drawn to scale. In fact, the dimensions may be arbitrarily increased or decreased for clarity of discussion. Wherever applicable and practical, like reference numerals refer to like elements throughout the drawings and written description.

FIGS. 1A to 1C are simplified cross-sectional views showing a method of singulating modules from a strip of multiple modules.

FIGS. 2A to 2D are simplified cross-sectional views showing a method of fabricating modules with solder bumps, after module singulation, according to a representative embodiment.

FIGS. 3A to 3D are simplified cross-sectional views showing a method of fabricating modules with solder bumps, after module singulation, according to another representative embodiment.

FIGS. 4A to 4B are simplified cross-sectional views showing initial steps of a method of fabricating modules with solder bumps, after module singulation, according to another representative embodiment.

FIGS. 5A to 5D are simplified cross-sectional views showing a conventional method of fabricating modules with solder bumps, before module singulation.

FIGS. 6A to 6D are simplified cross-sectional views showing an alternative conventional method of fabricating modules with solder bumps, before or after module singulation.

FIG. 7 is a simplified cross-sectional view showing a solder bump with a flattened surface formed by fabrication methods, according to representative embodiments disclosed herein.

FIG. 8 is a simplified cross-sectional view showing a solder bump with a flattened surface formed by conventional techniques.

### DETAILED DESCRIPTION

In the following detailed description, for purposes of explanation and not limitation, example embodiments disclosing specific details are set forth in order to provide a thorough understanding of the present teachings. However, it will be apparent to one of ordinary skill in the art having the benefit of the present disclosure that other embodiments according to the present teachings that depart from the specific details disclosed herein remain within the scope of the appended claims. Moreover, descriptions of well-known apparatuses and methods may be omitted so as to not obscure the description of the example embodiments. Such methods and apparatuses are clearly within the scope of the present teachings.

The terminology used herein is for purposes of describing particular embodiments only, and is not intended to be limiting. The defined terms are in addition to the technical, scientific, or ordinary meanings of the defined terms as commonly understood and accepted in the relevant context.

The terms “a”, “an” and “the” include both singular and plural referents, unless the context clearly dictates otherwise. Thus, for example, “a device” includes one device and plural devices. The terms “substantial” or “substantially” mean to within acceptable limits or degree to one of ordinary skill in the art. The term “approximately” means to within an acceptable limit or amount to one of ordinary skill in the art. Relative terms, such as “above,” “below,” “top,” “bottom,” “upper” and “lower” may be used to describe the various elements” relationships to one another, as illustrated in the accompanying drawings. These relative terms are intended to encompass different orientations of the device and/or elements in addition to the orientation depicted in the drawings. For example, if the device were inverted with respect to the view in the drawings, an element described as “above” another element, for example, would now be below that element. Where a first device or component is said to be connected or coupled to a second device or component, this encompasses examples where one or more intermediate devices or components may be employed to connect the two devices or components to each other. In contrast, where a first device or component is said to be directly connected or directly coupled to a second device or component, this encompasses examples where the two devices or components are connected together without any intervening devices or components other than electrical connectors (e.g., wires, bonding materials, etc.).

In various representative embodiments, solder paste is stencil printed on a flat non-wettable surface or applied to non-wettable surfaces of an embossed structure, and singulated solid state modules are placed on the printed solder paste, which is followed by reflow process. It is understood that solid state modules include all types of compatible modules and packages including PCBs and metal pads for soldering, such as land grid array (LGA) modules, quad flat no-lead (QFN) modules, chip scale packages (CSPs), and a wafer level packages (WLPs), for example, and will be referred to herein as “modules,” for the convenience of explanation. During the reflow process, the solder will melt and wet the metal pads on the modules, but will not wet the surface on which the solder paste was dispensed. All of the solder paste will therefore remain on the metal pads to result in a bumped metal part or a ball grid array (BGA) part depending upon solder volume and metal pad size. Due to the module's weight pressing on the solder paste during the reflow process, the molten solder will be flatten, somewhat, at the bottom surface, i.e., where the solder comes into contact with the non-wettable surface. This improves co-planarity and generally eliminates the need for a successive solder coining process, as discussed below.

According to a representative embodiment, a method is provided for forming solder bumps on at least one module comprising a PCB, electronic circuitry, and metal pads connected to the electronic circuitry, the metal pads being arranged in a predetermined pattern on a surface of the PCB. The method includes providing a planar structure comprising a non-wettable surface; placing a stencil over the non-wettable surface of the planar structure, the stencil defining openings corresponding to the predetermined pattern of the metal pads of the at least one module; applying solder paste through the openings in the stencil to provide corresponding solder paste deposits on the non-wettable surface of the planar structure; removing the stencil; placing the at least one module on the solder paste deposits, such that the metal pads align with the solder paste deposits, respectively; and reflowing the solder paste deposits to form corresponding solder bumps, which respectively adhere to the metal pads of the at least one module and not to the non-wettable surface of the planar structure.

According to another representative embodiment, a method is provided for forming solder bumps on at least one module comprising a PCB, electronic circuitry, and metal pads connected to the electronic circuitry, the metal pads being arranged in a predetermined pattern on a surface of the PCB. The method includes providing an embossed structure defining openings corresponding to the predetermined pattern of the metal pads of the at least one module, and comprising non-wettable surfaces, including within the openings of the embossed structure; applying solder paste in the openings of the embossed structure to provide corresponding solder paste deposits on the non-wettable surfaces of the embossed structure; placing the at least one module on the solder paste deposits, such that the metal pads align with the solder paste deposits, respectively; and reflowing the solder paste deposits to form corresponding solder bumps, which respectively adhere to the metal pads of the at least one module and not to the non-wettable surfaces of the embossed structure.

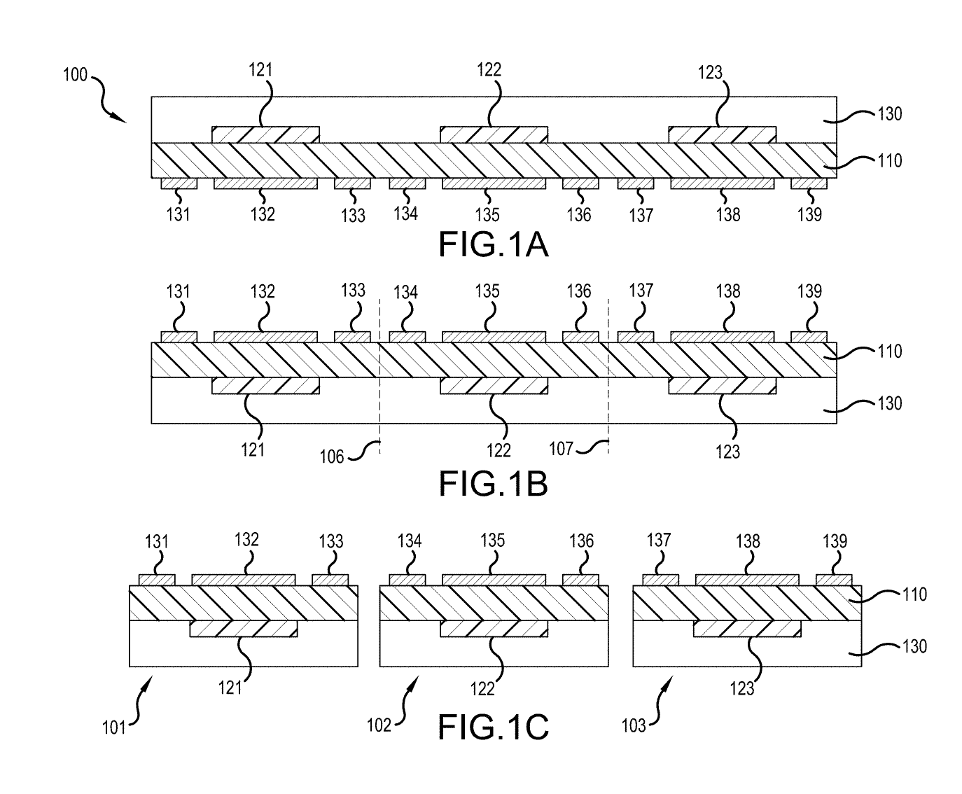

Referring to FIG. 1A, strip 100 includes a printed circuit board (PCB) 110 provided in a sheet. The PCB 110 is formed of multiple layers of “prepeg” material, with electronic circuitry and/or components formed between and within the layers. The prepeg material generally includes a base material, such as glass fabric impregnated with resin, and is compressed and laminated with layers patterned metal or other conductors. Electronic components, such as acoustic filters, flipped chip integrated circuits (ICs), and surface mounted technology (SMT) components, for example, may be mounted to a surface of the PCB 110, as indicated by representative electronic components 121, 122 and 123. A molded compound 130 is disposed over the PCB 110 and the electronic components 121, 122 and 123. The molded compound 130 may be formed of a reinforced or non-reinforced epoxy resin, for example, and may be applied using any process compatible with fabrication of semiconductor devices, such as injection molding, transfer molding, or compression molding, for example. The molded compound 130 generally protects the electronic components 121, 122 and 123, and provides additional structural support. The molded compound 130 may also hermetically seal the electronic components 121, 122 and 123 within the individual modules (e.g., representative module 101, 102 and 103, depicted in FIG. 1C).

Electrically and/or thermally conductive pads are provided on an opposite surface of the PCB 110, as indicated by representative metal pads 131-139. The metal pads 131-139 may be preformed on the PCB 110, as part of a package. Alternatively, the metal pads 131-139 may be formed on the PCB 110 by flipping the PCB 110, as shown in FIG. 1B, and applying the metal pads 131-139 to the opposite surface of the PCB 110. The metal pads 131-139 are provided in sets, corresponding to the individual modules 101, 102 and 103 to be produced, and configured to match contacts of devices (e.g., wireless communication devices, computer boards, and the like) to which the individual modules 101, 102 and 103 will ultimately be attached. That is, metal pads 131-133 correspond to module 101, metal pads 134-136 correspond to module 102, and metal pads 137-139 correspond to module 103. The metal pads 131-139 may be formed of various electrically and/or thermally conductive materials, such as copper (Cu), silver (Ag), gold (Au), or nickel (Ni), for example.

Referring to FIG. 1B, the strip 100, including the PCB 110 together with the electronic components 121, 122 and 123, the molded compound 130 and the metal pads 131-139, is flipped. The strip 100 is then singulated, e.g., by sawing, laser dicing, scribing and breaking, or other technique, into individual modules 101, 102 and 103, indicated by dashed vertical lines 106 and 107. FIG. 1C shows the singulated modules 101, 102 and 103.

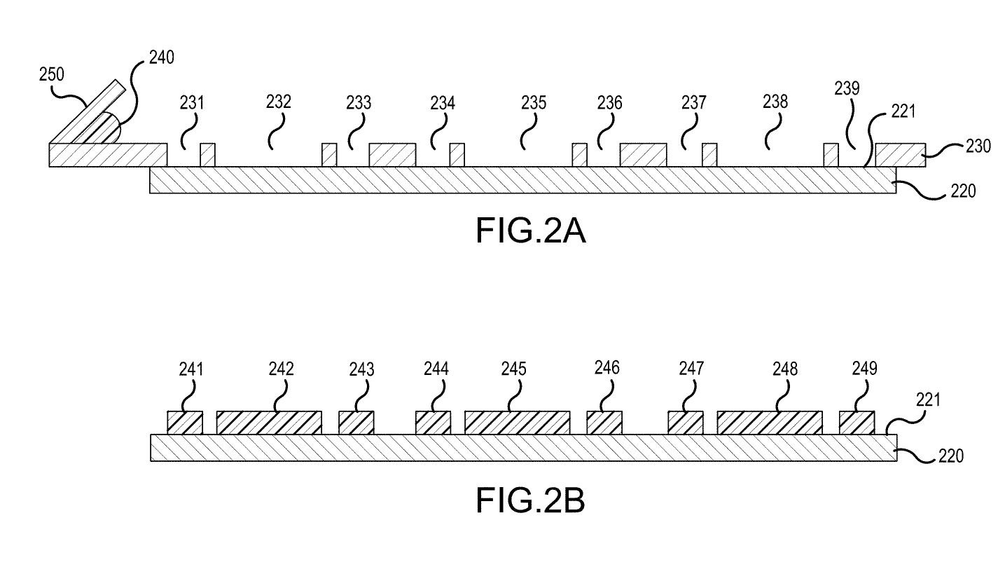

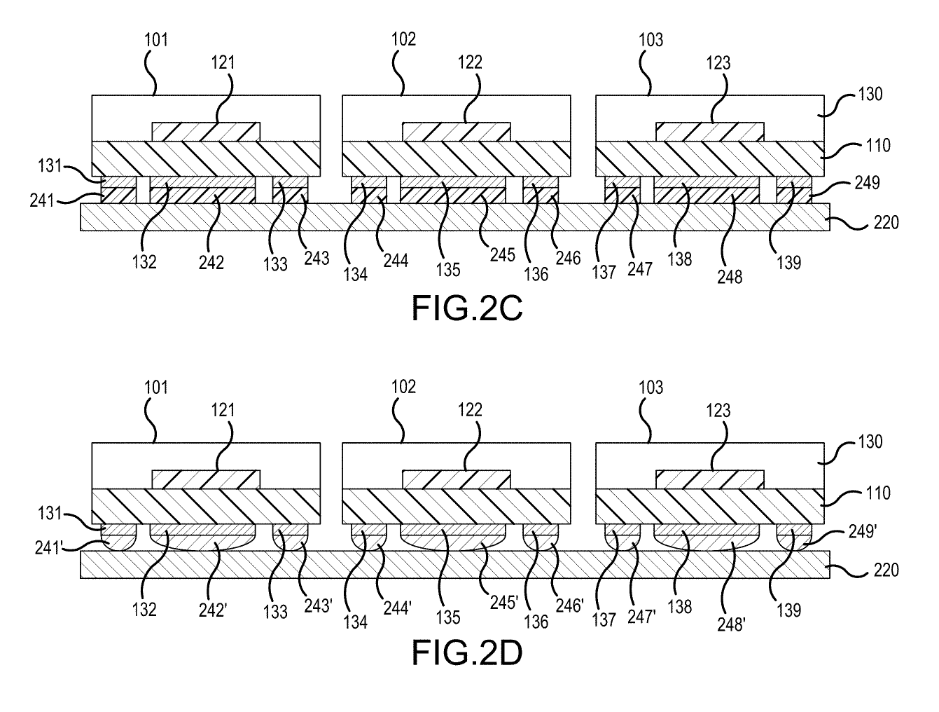

FIGS. 2A to 2D are simplified cross-sectional views showing a method of fabricating modules with solder bumps, after module singulation, according to a representative embodiment.

Referring to FIG. 2A, a planar structure 220 is provided, where the planar structure 220 includes a flat, a non-wettable surface 221. The non-wettable surface 221 comprises a material (e.g., non-wettable material) to which solder and/or solder paste does not stick or adhere. For example, the non-wettable surface 221 may be formed of polytetrafluoroethylene (PTFE), perfluoroalkoxy (PFA), steel, glass or silicon, although other materials may be incorporated without departing from the scope of the present teachings. In various embodiments, the planar structure may be formed entirely of the non-wettable material, or only the planar non-wettable surface may be formed of the non-wettable material and the remainder of the planar structure may be formed of a different material, providing structural support for the non-wettable material.

A stencil 230 is placed over the non-wettable surface 221 of the planar structure 220, the stencil 230 defines openings 231-239 corresponding to a predetermined pattern of the metal pads of each of the modules, such as the metal pads 131-139 on the representative modules 101, 102 and 103, respectively. The stencil 230 may be formed by machining or laser etching a sheet of metal, such as stainless steel, for example, before the stencil 230 is placed over the non-wettable surface 221. The stencil 230 alternatively may be formed by photolithography or any other means for applying the predetermined pattern of metal pads 131-139, for example. In various embodiments, the stencil 230 and/or the planar structure 220 may be reusable, thus providing cost savings.

Referring to FIGS. 2A and 2B, solder paste (e.g., from solder paste source 240) is applied through the openings 231-239 in the stencil 230 to provide corresponding solder paste deposits 241-249 on the non-wettable surface 221 of the planar structure 220. The solder paste may be a mixture of solder (e.g., an alloy of tin and lead or tin, silver and copper) and flux, and has a sticky consistency. Like the openings 231-239 in the stencil 230, the solder paste deposits 241-249 correspond to the predetermined pattern of metal pads 131-139 of the representative modules 101, 102 and 103, respectively. In an embodiment, the solder paste may be applied by spreading the solder paste from the solder paste source 240, initially provided at one end of the stencil 230, over the top surface of the stencil 230 using a squeegee 250. The squeegee 250 may be manipulated manually or may be automated. Downward pressure applied to the squeegee 250 (toward the top surface of the stencil 230) while spreading the solder paste from the solder paste source 240 forces the solder paste into the stencil openings 231-239. The pliability of the solder paste results in each of the stencil openings 231-239 being substantially filled with the solder paste to form the solder paste deposits 241-249. The stencil 230 is then removed, leaving the solder paste deposits 241-249 on the non-wettable surface 221 of the planar structure 220, as shown in FIG. 2B.

Referring to FIG. 2C, the modules 101, 102 and 103 are placed on the solder paste deposits 241-249, with the metal pads 131-139 facing downward, such that the metal pads 131-139 align with the solder paste deposits 241-249, respectively. More particularly, the metal pads 131-133 of the module 101 are aligned with and placed on the solder paste deposits 241-243, respectively; the metal pads 134-136 of the module 102 are aligned with and placed on the solder paste deposits 244-246, respectively; and the metal pads 137-139 of the module 103 are aligned with and placed on the solder paste deposits 247-249, respectively. The modules 101, 102 and 103 may be aligned and placed on the solder paste deposits 241-249 using automated pick and place equipment, for example, such as chipshooters, as would be apparent to one of ordinary skill in the art. Such pick and place equipment may have multiple robotic heads for placing the modules 101, 102 and 103 simultaneously on various locations, thereby improving throughput.

Referring to FIG. 2D, the solder paste deposits 241-249 are reflowed to form corresponding solder bumps 241′-249′, respectively. As the solder bumps 241′-249′ cool, they respectively adhere to (or bond with) the metal pads 131-139 of the modules 101-103. The solder bumps 241′-249′ do not adhere to or otherwise react with the non-wettable surface 221 of the planar structure 220, typically enabling the modules 101-103 to be lifted off of the planar structure 220 after cooling. Depending on the amount and stickiness of flux residue after reflowing the solder paste deposits 241-249, cleaning of the flux residue may be required before the lifting off of the modules 101-103 from the planar structure 220.

The solder paste deposits 241-249 are reflowed by temporarily applying heat to the assembled structure shown in FIG. 2C, for example, causing the solder paste deposits 241-249 to melt. For example, the whole assembly, including the planar structure 220, the modules 101-103, and the solder paste deposits 241-249 may be heated by placing them in a heated environment, such as a reflow oven. The heated environment may contain an excess of nitrogen to enable better wettable of the solder bumps 241′-249′ to the metal pads 131-139, respectively, and to prevent oxidation of solder bumps 241′-249′ at high temperatures. When the solder paste deposits 241-249 are in the melted or molten state, they become substantially rounded (effectively forming a half circle or half ellipse).

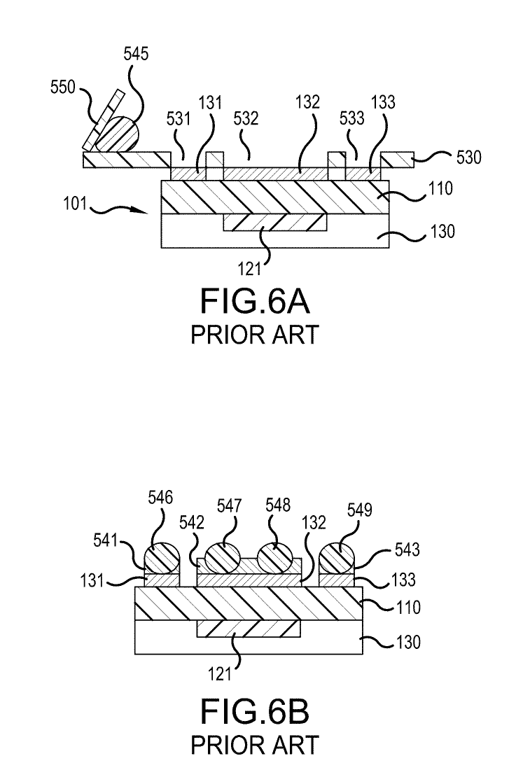

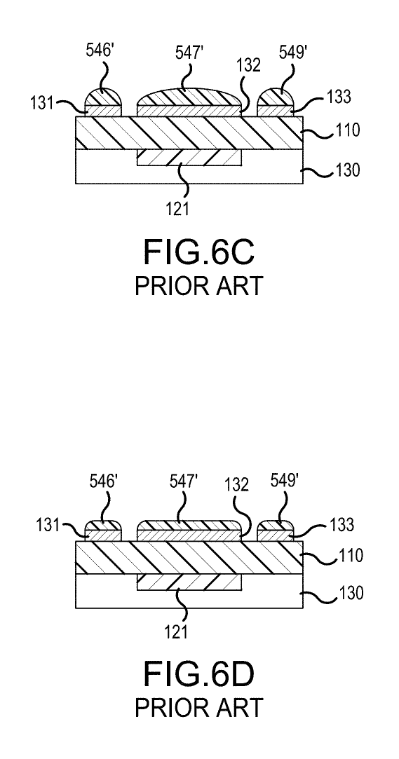

Further, the corresponding weights of the modules 101-103 compress the melted solder paste deposits 241-249, respectively, causing a surface at the center of each of the resulting solder bumps 241′-249′ to flatten against the non-wettable surface 221 of the planar structure 120. An example of a solder bump with a surface having been flattened against a non-wettable surface is shown in FIG. 6. Each of the flattened surfaces of the solder bumps 241′-249′ is substantially uniform, and smoothly transitions to the rounded side surface since the flattening process occurs naturally due to the evenly applied pressure on the melted, rounded solder paste deposits 241-249. Also, because the non-wettable surface 221 is planar, the flattened surfaces of each of the groups for solder bumps 241′-243′, 244′-246′ and 247′-249′are substantially co-planar with one another, initially after reflowing the solder paste deposits 241-249 (that is, prior to subsequent warping of the corresponding modules 101, 102 and 103 during cooling).

Because the above process adds the solder bumps 241′-249′ after singulation of the completed modules 101-103, the circuits and/or components of the modules 101-103 may be tested at the module level as opposed to at the strip level (i.e., before singulation), which may be easier (e.g., due to higher strip warpage as opposed to lower unit warpage) and may provide more targeted and accurate test results. Moreover, the modules 101-103 may be tested at the module level prior to application of solder paste. In comparison, testing after application of solder paste (and/or formation of solder bumps), as in conventional methods, may result in contamination of test equipment, require frequent cleaning adding to cost, provide inaccurate results, and lead to solder bump damage. Thus, the modules 101, 102 and 103 may be shipped, with the respective sets of solder bumps 241′-243′, 244′-246′ and 247′-249′ already attached, and already tested at the module level (prior to application of solder paste) by the manufacturer.

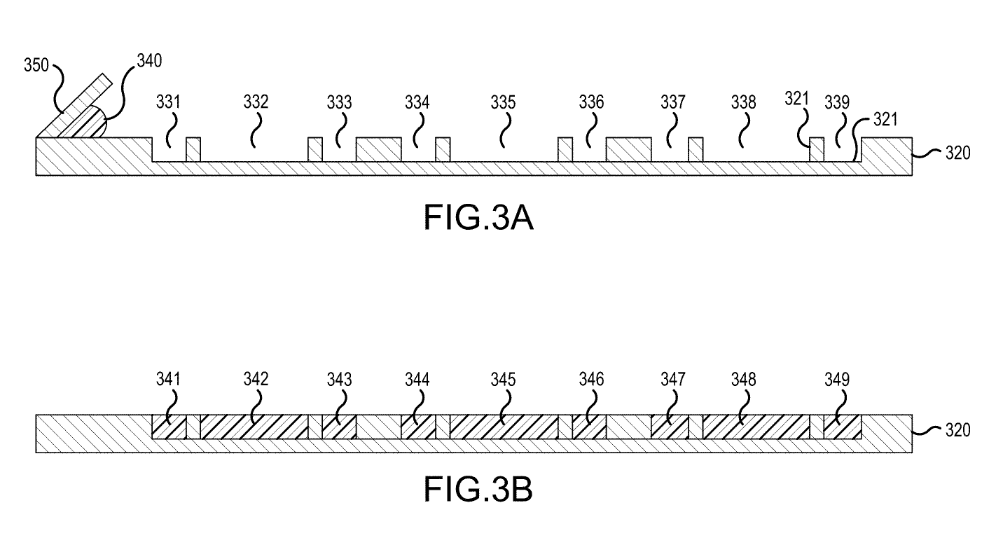

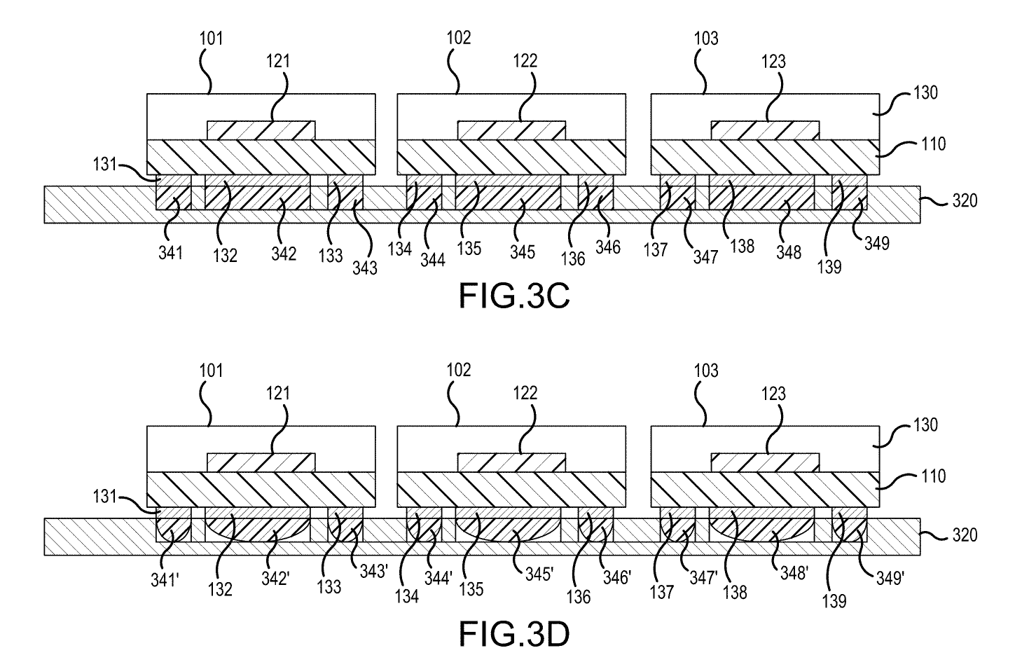

FIGS. 3A to 3D are simplified cross-sectional views showing another method of fabricating modules with solder bumps, after module singulation, according to a representative embodiment.

Referring to FIG. 3A, an embossed structure 320 is provided. The embossed structure 320 defines openings 331-339, and thus includes multiple substantially horizontal and vertical surfaces, which are collectively referred to as non-wettable surface 321, for convenience of description. The non-wettable surface 321 comprises a material (e.g., non-wettable material) to which solder and/or solder paste does not stick or adhere. For example, the non-wettable surface 321 may be formed of PTFE, PFA, steel, glass or silicon, although other materials may be incorporated without departing from the scope of the present teachings. In various embodiments, the embossed structure 320 may be formed entirely of the non-wettable material, or only the exposed substantially horizontal and vertical surfaces defining the openings 331-339 (and the surface connections there between) may be formed of the non-wettable material and the remainder of the embossed structure 320 may be formed of a different material, providing structural support for the non-wettable material.

Referring to FIG. 3B, solder paste (e.g., from solder paste source 340) is applied through the openings 331-339 in the embossed structure 320 to provide corresponding solder paste deposits 341-349 on the non-wettable surface 321 of the embossed structure 320. Due to the openings 331-339 in the embossed structure 320, depositing of solder paste may be accomplished without the use of a stencil, such as the stencil 230 described with reference to FIG. 2A. Like the openings 331-339 in the embossed structure 320, the solder paste deposits 341-349 correspond to the predetermined pattern of metal pads 131-139 of the representative modules 101, 102 and 103, respectively. In an embodiment, the solder paste may be applied by spreading the solder paste from the solder paste source 340, initially provided at one end of the embossed structure 320, over the top surface of the embossed structure 320 using a squeegee 350. The squeegee 350 may be manipulated manually or may be automated. Downward pressure applied to the squeegee 350 (toward the top surface of the embossed structure 320) while spreading the solder paste from the solder paste source 340 forces the solder paste into the openings 331-339. The pliability of the solder paste results in each of the openings 331-339 being substantially filled with the solder paste to form the solder paste deposits 341-349.

Referring to FIG. 3C, the modules 101, 102 and 103 are placed on the solder paste deposits 341-349, with the metal pads 131-139 facing downward, such that the metal pads 131-139 align with the solder paste deposits 341-349, respectively. More particularly, the metal pads 131-133 of the module 101 are aligned with and placed on the solder paste deposits 341-343, respectively; the metal pads 134-136 of the module 102 are aligned with and placed on the solder paste deposits 344-346, respectively; and the metal pads 137-139 of the module 103 are aligned with and placed on the solder paste deposits 347-349, respectively.

Referring to FIG. 3D, the solder paste deposits 341-349 are then reflowed to form corresponding solder bumps 341′-349′, respectively, within the corresponding openings 331-339. As the solder bumps 341′-349′ cool, they respectively adhere to (or bond with) the metal pads 131-139 of the modules 101-103. The solder bumps 341′-349′ generally do not adhere to or otherwise react with the non-wettable surface 321 of the embossed structure 320, within the openings 331-339 or otherwise, enabling the modules 101-103 to be lifted off of the embossed structure 320 after cooling. However, as mentioned above, depending on the amount and stickiness of flux residue after reflowing the solder paste deposits 341-349, cleaning of the flux residue may be required before the lifting off of the modules 101-103 from the embossed structure 320. When the solder paste deposits 341-349 are in a melted or molten state during reflow, they become substantially rounded (effectively forming a half circle or half ellipse).

Further, the corresponding weights of the modules 101-103 compress the melted solder paste deposits 341-349, respectively, causing a surface at the center of each of the resulting solder bumps 341′-349′ to flatten against the non-wettable surface 321 of at the bottom of each of the openings 331-339 in the embossed structure 320. Again, an example of a solder bump with a surface having been flattened against a non-wettable surface is shown in FIG. 6. As discussed above with reference to FIG. 2D, each of the flatten surfaces of the solder bumps 341′-349′ is substantially uniform, and smoothly transitions to the rounded side surfaces since the flattening process occurs naturally due to the evenly applied pressure on the melted, rounded solder paste deposits 341-349. Also, in an embodiment, the bottoms of each of the openings 331-339 are co-planar. Therefore, the flattened surfaces of each of the groups for solder bumps 341′-343′, 344′-346′ and 347′-349′ are substantially co-planar with one another, initially after reflowing the solder paste deposits 341-349 (that is, prior to subsequent warping of the corresponding modules 101, 102 and 103 during cooling).

As discussed above, because the above process adds the solder bumps 341′-349′ after singulation of the completed modules 101-103, the circuits and/or components of the modules 101-103 may be tested at the module level as opposed to at the strip level (i.e., before singulation), which may be easier (due to higher strip warpage as opposed to lower unit warpage) and may provide more targeted and accurate test results. Moreover, the modules 101-103 may be tested at the module level prior to application of solder paste. In comparison, testing after application of solder paste (and/or formation of solder bumps), as in conventional methods, may result in contamination of test equipment, require frequent cleaning adding to cost, provide inaccurate results, and lead to solder bump damage. Thus, the modules 101, 102 and 103 may be shipped, with the respective sets of solder bumps 341′-343′, 344′-346′ and 347′-349′ already attached, and already tested at the module level (prior to application of solder paste) by the manufacturer.

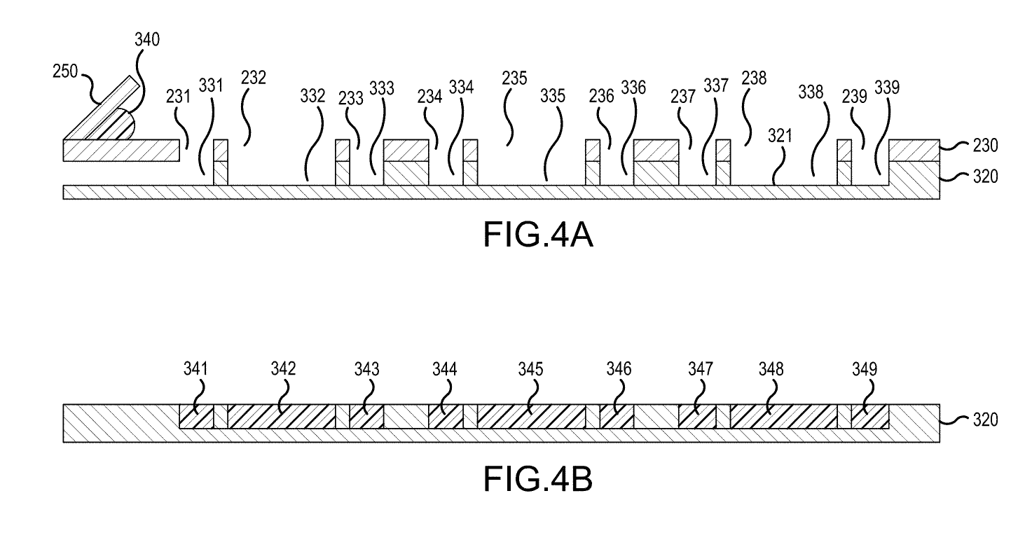

FIGS. 4A to 4B are simplified cross-sectional views showing initial steps of a method of fabricating modules with solder bumps, after module singulation, according to another representative embodiment. More particularly, FIGS. 4A and 4B combine use of a stencil, such as stencil 230 shown in FIG. 2A, with use of an embossed structure having a non-wettable surface, such as embossed structure 320 shown in FIGS. 3A to 3D.

Referring to FIG. 4A, stencil 230 is placed over the non-wettable surface 321 of the embossed structure 320. The stencil 230 defines openings 231-239, which correspond to the metal pads 131-139 on the representative modules 101, 102 and 103, respectively, and the embossed structure 320 defines openings 331-339, which likewise correspond to the metal pads 131-139 on the representative modules 101, 102 and 103, respectively. As discussed above, the stencil 230 may be formed by machining or laser etching a sheet of metal, such as stainless steel, for example, before the stencil 230 is placed over the non-wettable surface 321. The stencil 230 alternatively may be formed by photolithography or any other means for applying the predetermined pattern of metal pads 131-139, for example. In various embodiments, the stencil 230 and/or the embossed structure 320 may be reusable, thus providing cost savings.

As discussed above, solder paste (e.g., from solder paste source 340) is applied through the openings 231-239 in the stencil 230 and the openings 331-339 in the embossed structure 320 to provide corresponding solder paste deposits 341-349 on the non-wettable surface 321 of the embossed structure 320. Like the openings 231-239 and 341-349, the solder paste deposits 341-349 correspond to the predetermined pattern of metal pads 131-139 of the representative modules 101, 102 and 103, respectively. In an embodiment, the solder paste may be applied by spreading the solder paste from the solder paste source 340, initially provided at one end of the stencil 230, over the top surface of the stencil 230 using a squeegee 250. The squeegee 250 may be manipulated manually or may be automated. Downward pressure applied to the squeegee 250 (toward the top surface of the stencil 230) while spreading the solder paste from the solder paste source 340 forces the solder paste into the stencil openings 231-239 and the embossed structure openings 331-339. The pliability of the solder paste results in each of the openings 331-339 being substantially filled with the solder paste to form the solder paste deposits 341-349, as shown in FIG. 4B, for example.

The modules 101, 102 and 103 may be placed on the solder paste deposits 341-349, with metal pads 131-139 facing downward, such that the metal pads 131-139 align with the solder paste deposits 341-349, respectively, as discussed above with reference to FIG. 3C. Further, the solder paste deposits 341-349 may be reflowed to form corresponding solder bumps 341′-349′, respectively, within the corresponding openings 331-339 of the embossed structure 320 as discussed above with reference to FIG. 3D. Accordingly, descriptions of these steps will not be repeated.

An advantage of the initial steps depicted in FIGS. 4A and 4B, which combine use of the stencil 230 and the embossed structure 320, is that the repeated action of a squeegee (e.g., squeegee 350 shown in FIG. 3A) over the non-wettable surface 321 of the (reusable) embossed structure 320 may cause wear and tear over time. Thus, by including the stencil 230, which may be formed of a more durable material than the embossed structure 320, the repeated action of the squeegee 250 will not cause the same level of wear and tear. Also, to the extent wear and tear does occur and becomes excessive with respect to the stencil 230, the stencil 230 can be more easily and less expensively replaced than the embossed structure 320. Another advantage is that the openings 331-339 in the embossed structure 320 are generally better at keeping the solder paste deposits 341-349 and in turn the modules 101, 102 and 103 in place after reflow than the planar structure 220.

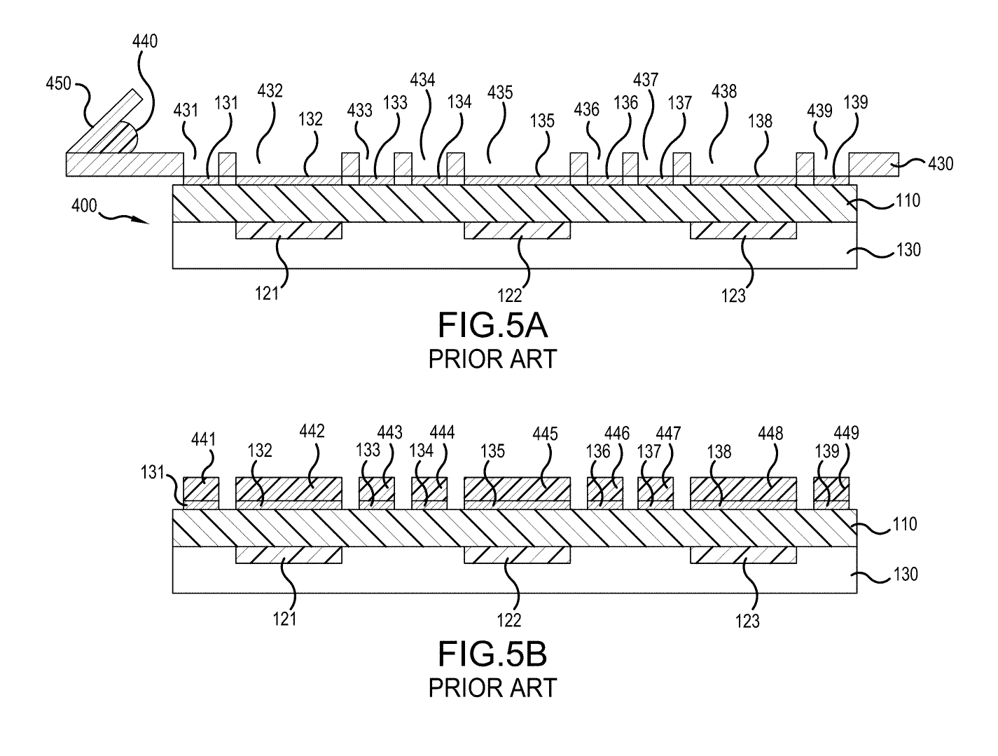

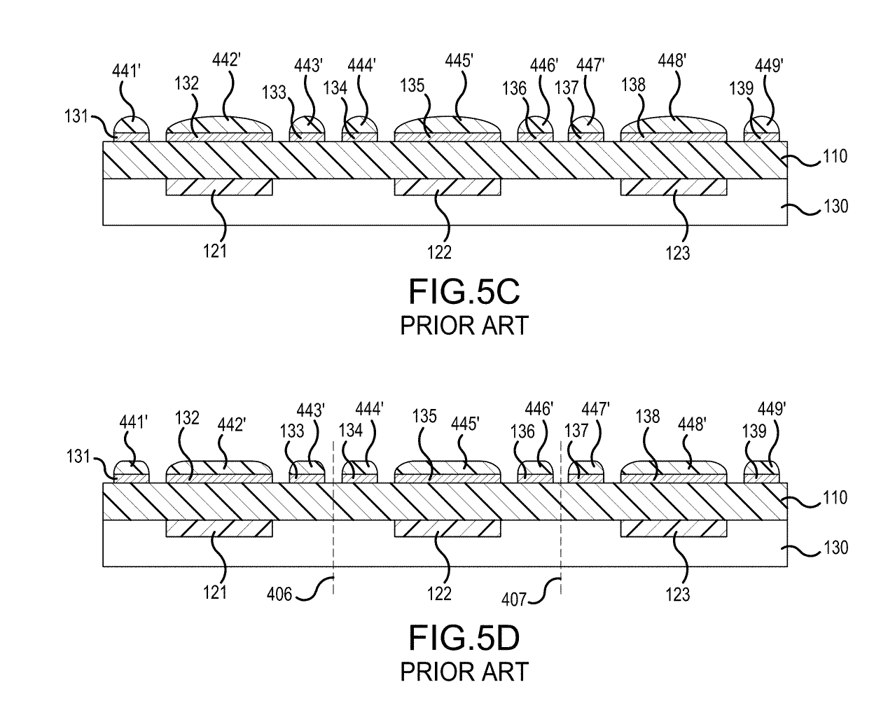

For purposes of comparison, conventional methods of fabricating modules are described below. FIGS. 5A to 5D are simplified cross-sectional views showing a conventional method of fabricating modules with solder bumps, before module singulation, and FIGS. 6A to 6D are simplified cross-sectional views showing an alternative conventional method of fabricating modules with solder bumps, after module singulation.

Referring to FIG. 5A, a stencil 430 is placed over the surface of the PCB 110 of strip 400 prior to module singulation. More particularly, the stencil 430 is placed on the surface of the PCB 110 on which the metal pads 131-139 have been formed. The stencil 430 defines openings 431-439 corresponding to the predetermined pattern of the metal pads 131-139, respectively. Referring to FIG. 5B, solder paste (e.g., from solder paste source 440) is applied through the openings 431-439 in the stencil 430 to provide corresponding solder paste deposits 441-449 on the metal pads 131-139, respectively. As discussed above, the solder paste from the solder paste source 440 may be applied using a squeegee 450.

Referring to FIG. 5C, the solder paste deposits 441-449 are reflowed to form corresponding solder bumps 441′-449′, respectively. As the solder bumps 441′-449′ cool, they respectively adhere to the metal pads 131-139, respectively. When the solder paste deposits 441-449 are in the melted or molten state, they become substantially rounded (effectively forming a half circle or half ellipse). Referring to FIG. 5D, the top surfaces of each of the resulting solder bumps 441′-449′ are deformed using a conventional coining process, for example, to create flattened top surfaces. The strip 400 is then singulated, e.g., by sawing, laser dicing, scribing and breaking, or other technique, as indicated by dashed vertical lines 406 and 407.

Because the above process adds the solder bumps 441′-449′ before singulation of the completed modules, the circuits and/or components of the modules are tested while still in sheet form (i.e., not at the module level) before application of solder paste, or tested at the module level after application of solder paste and subsequent singulation. As mentioned above, this may result in contamination of test equipment and inaccurate results.

FIGS. 6A to 6D depict another conventional method of fabricating modules with solder bumps before or after module singulation. For convenience of explanation, the method is described with reference to a representative singulated module 101, although the various steps may be applied substantially simultaneously to multiple modules prior to singulation, followed by a separation process. Referring to FIG. 6A, a stencil 530 is placed over the surface of the PCB 110 of the module 101. More particularly, the stencil 530 is placed on the surface of the PCB 110 on which the metal pads 131-133 have been formed. The stencil 530 defines openings 531-533 corresponding to the predetermined pattern of the metal pads 131-133, respectively.

Referring to FIG. 6B, flux (e.g., from flux source 545) is applied, e.g., using squeegee 550, through the openings 531-533 in the stencil 530 to provide corresponding flux deposits 541-543 on the metal pads 131-133, respectively. In the alternative, the flux may be applied using any various methods, involving dispensing, jetting, dotting, spraying or pin transferring techniques, for example. The stencil 530 is then removed, and preformed solder balls 546-549 are “dropped” into the flux deposits 541-543. In particular, solder ball 546 is placed into the flux deposit 541; solder balls 547 and 548 are placed into the flux deposit 542; and solder ball 549 is placed into the flux deposit 543.

Referring to FIG. 6C, the solder balls 546-549 are reflowed to form solder bump 546′ corresponding to solder ball 546, solder bump 547′ corresponding to solder balls 547 and 548 (which join during the reflow process), and solder bump 549′ corresponding to solder ball 549. As the solder bumps 546′, 547′ and 549′ cool, they respectively adhere to the metal pads 131, 132 and 133, respectively. When the solder balls 546-549 are in the melted or molten state, they become substantially rounded (effectively forming a half circle or half ellipse). Referring to FIG. 6D, the top surfaces of each of the solder bumps 546′, 547′ and 549′ are deformed using a conventional coining process, for example, to create flattened top surfaces.

Because the above process adds the stencil 530, the flux deposits 541-543, and the solder balls bumps 546′-549′ after singulation to each module (e.g., module 101), the process is inefficient and labor intensive. Also, if implemented at a strip level, the process of FIGS. 6A to 6B have substantially the same disadvantages as the process described above with reference to FIGS. 5A to 5D.

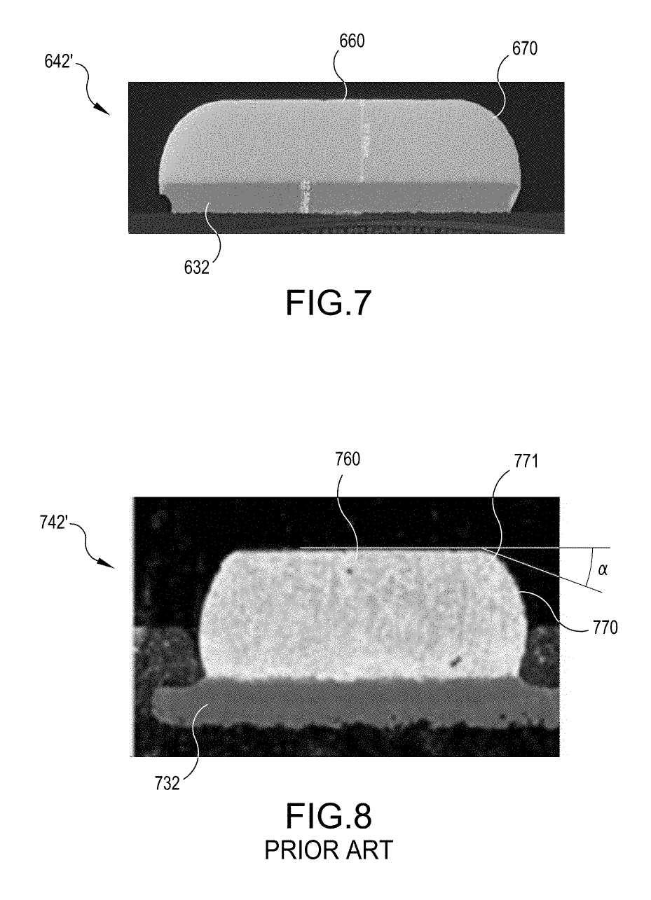

FIG. 7 is a simplified cross-sectional view showing a solder bump with a flattened surface, which may be formed by any of the fabrication methods, according to representative embodiments herein. For purposes of comparison, FIG. 8 is a simplified cross-sectional view showing a solder bump with a flattened surface formed by conventional techniques, such as coining.

Referring to FIG. 7, illustrative solder bump 642′ is attached to illustrative metal pad 632, and has been formed by reflowing a corresponding solder paste deposit, according to any of the embodiments of the disclosure described herein. The solder bump 642′ is flat (e.g., horizontal in the depicted orientation of FIG. 7) at center portion 660 (e.g., top surface) and curved at rounded portions 670 (e.g., side surfaces), where a smooth transition is provided from the flat center portion 660 to the curved rounded portions 670. Also, the solder bump 642′ is substantially symmetrical in cross-sectional shape with respect to the transition from the center portion 660 to the rounded portions 670. As explained above, e.g., with reference to FIGS. 2D and 3D, the flat center portion 660 is formed by the weight of a module compressing a corresponding melted solder paste deposit against a non-wettable surface, such as illustrative non-wettable surfaces 221 and 321. That is, the smooth transition from the flat center portion 660 to the curved rounded portions 670 occurs naturally due to the evenly applied pressure on the melted, rounded solder paste deposit.

In comparison, referring to FIG. 8, illustrative solder bump 742′ is attached to illustrative metal pad 732, and has been formed by reflowing a corresponding solder paste deposit or by reflowing a preformed solder ball within a corresponding flux deposit, for example, followed by metal working, such as coining The solder bump 742′ is flat at center portion 760 (e.g., top surface) and curved at rounded portions 770 (e.g., side surfaces). However, there is not a smooth transition provided between the flat center portion 760 and the curved rounded portions 770. Rather, a distinct edge 771 is formed around an outer perimeter of the flat center portion 760, defining a boundary between the flat center portion 760 and the curved rounded portions 770. The distinct edge 771 is salient in that an angle α (greater than zero) is formed between an imaginary line extending along the relatively horizontal flat center portion 760 and an imaginary line extending along the drop-off from the distinct edge 771 to the curved rounded portion 770, as shown in FIG. 8. Also, the conventionally formed solder bump 742′ may be less symmetrical in cross-sectional shape than the solder bump 642′ in that the flat center portion 760 is formed by metal working, such as coining or other mechanical process, after the solder bump 742′ has substantially cooled and hardened.

The various methods, components, structures and parameters are included by way of illustration and example only and not in any limiting sense. In view of this disclosure, those skilled in the art can implement the present teachings in determining their own applications and needed methods, components, materials, structures and equipment to implement these applications, while remaining within the scope of the appended claims.

What is claimed:

1. A method of forming solder bumps on at least one module comprising a printed circuit board (PCB), electronic circuitry, and metal pads connected to the electronic circuitry, the metal pads being arranged in a predetermined pattern on a surface of the PCB, the method comprising:
providing a planar structure comprising a non-wettable surface;
placing a stencil over the non-wettable surface of the planar structure, the stencil defining openings corresponding to the predetermined pattern of the metal pads of the at least one module;
applying solder paste through the openings in the stencil to provide corresponding solder paste deposits on the non-wettable surface of the planar structure;
removing the stencil;
placing the at least one module on the solder paste deposits, such that the metal pads align with the solder paste deposits, respectively; and
reflowing the solder paste deposits to form corresponding solder bumps, which respectively adhere to the metal pads of the at least one module and not to the non-wettable surface of the planar structure.

2. The method of claim 1, wherein applying the solder paste comprises spreading the solder paste over a top surface of the stencil using a squeegee.

3. The method of claim 1, wherein, while reflowing the solder paste deposits, a weight of the at least one module compresses the solder paste deposits, causing a surface of each of the corresponding solder bumps to flatten against the non-wettable surface of the planar structure.

4. The method of claim 3, wherein the flattened surfaces of the solder bumps are substantially co-planar initially after reflowing the solder paste deposits, prior to subsequent warping of the at least one module during cooling.

5. The method of claim 1, wherein the non-wettable surface of the planar structure comprises polytetrafluoroethylene (PTFE), perfluoroalkoxy (PFA), steel, glass or silicon.

6. The method of claim 1, wherein the metal pads comprise at least one of copper, silver, gold or nickel, and the solder paste comprises a mixture of solder and flux in predetermined proportions.

7. The method of claim 1, wherein the at least one module comprises a land grid array (LGA) module, a quad flat no-lead (QFN) module, a chip scale package (CSP), or a wafer level package (WLP).

8. The method of claim 1, wherein the electronic circuitry of the at least one module is tested prior to placing the at least one module on the solder paste deposits on the non-wettable surface of the planar structure.

9. The method of claim 1, further comprising:
removing the at least one module with the adhered solder bumps from the planar structure.

10. A method of forming solder bumps on at least one module comprising a printed circuit board (PCB), electronic circuitry, and metal pads connected to the electronic circuitry, the metal pads being arranged in a predetermined pattern on a surface of the PCB, the method comprising:
providing an embossed structure defining openings corresponding to the predetermined pattern of the metal pads of the at least one module, and comprising non-wettable surfaces, including within the openings of the embossed structure;
applying solder paste in the openings of the embossed structure to provide corresponding solder paste deposits on the non-wettable surfaces of the embossed structure;
placing the at least one module on the solder paste deposits, such that the metal pads align with the solder paste deposits, respectively; and
reflowing the solder paste deposits to form corresponding solder bumps, which respectively adhere to the metal pads of the at least one module and not to the non-wettable surfaces of the embossed structure.

11. The method of claim 10, wherein applying the solder paste comprises spreading the solder paste over a top surface of the embossed structure using a squeegee.

12. The method of claim 10, wherein, while reflowing the solder paste deposits, a weight of the at least one module compresses the solder paste deposits, causing a surface of each of the corresponding solder bumps to flatten against the non-wettable surfaces within the openings of the embossed structure, respectively.

13. The method of claim 12, wherein the flattened surfaces of the solder bumps are substantially co-planar initially after reflowing the solder paste deposits, prior to subsequent warping of the at least one module during cooling.

14. The method of claim 10, wherein the non-wettable surfaces of the embossed structure comprise polytetrafluoroethylene (PTFE), perfluoroalkoxy (PFA), steel, glass or silicon.

15. The method of claim 10, wherein the metal pads comprise at least one of silver, copper, gold or nickel, and the solder paste comprises a mixture of solder and flux in predetermined proportions.

16. The method of claim 10, wherein the at least one module comprises a land grid array (LGA) module, a quad flat no-lead (QFN) module, a chip scale package (CSP), or a wafer level package (WLP).

17. The method of claim 10, wherein the electronic circuitry of the at least one module is tested prior to placing the at least one module on the solder paste deposits in the openings of the embossed structure.

18. The method of claim 10, further comprising:
removing the at least one module with the adhered solder bumps from the embossed structure.

19. A solid state module, comprising:
a printed circuit board (PCB),
electronic circuitry formed, at least in part, within the PCB, the electronic circuitry including at least one electronic component;
mold compound encapsulating the at least one electronic component;
a plurality of metal pads connected to the electronic circuitry, the metal pads being arranged in a predetermined pattern on a surface of the PCB; and
a plurality of solder bumps attached to the plurality of metal pads, respectively, each solder bump including a surface having a flat center portion, facing away from the metal pad to which the solder bump is attached, and side surfaces having curved rounded portions,
wherein the flat center portion of each solder bump smoothly transitions into the curved rounded portions, with no distinct edges defining a boundary between the flat center portion and the curved rounded portions.

20. The solid state module of claim 19, wherein the plurality of metal pads comprise a plurality of land grid array (LGA) pads.
